(19) United States
(12) Patent Application Publication
(10) Pub. No.: US 2017/0309491 A1
(43) Pub. Date: Oct. 26, 2017

(54) METHOD OF FORMING TUNGSTEN FILM AND METHOD OF FABRICATING SEMICONDUCTOR DEVICE USING THE SAME

(71) Applicant: Samsung Electronics Co., Ltd., Suwon-si (KR)

(72) Inventors: Jun-ku AHN, Hwaseong-si (KR); Ji-hoon KIM, Gwacheon-si (KR); Seong-hun PARK, Hwaseong-si (KR); Youn-jae CHO, Anyang-si (KR); Hee-sook PARK, Hwaseong-si (KR); Woong-hee SOHN, Seoul (KR)

(73) Assignee: Samsung Electronics Co., Ltd., Suwon-si (KR)

(21) Appl. No.: 15/369,202

(22) Filed: Dec. 5, 2016

(30) Foreign Application Priority Data
Apr. 21, 2016 (KR) 10-2016-0048953

(51) Int. Cl. H01L 21/285; C23C 16/06; H01L 27/108

(52) U.S. Cl. CPC H01L 21/28562; H01L 27/10891; C23C 16/06; H01L 21/28568

(57) ABSTRACT

A method of forming a tungsten film including disposing a substrate inside a process chamber; performing a tungsten nucleation layer forming operation for forming a tungsten nucleation layer on the substrate, performing a first operation for forming a portion of a tungsten bulk layer on the tungsten nucleation layer by alternately supplying a tungsten-containing gas and a reducing gas into the process chamber, and performing a second operation for stopping the supply of the tungsten-containing gas and the reducing gas and removing a remaining gas in the process chamber may be provided. The first operation and the second operation may be repeated at least twice until the tungsten bulk layer reaches a desired thickness.

### CROSS-REFERENCE TO RELATED APPLICATION

This application claims priority under 35 U.S.C. §119 to Korean Patent Application No. 10-2016-0048953, filed on Apr. 21, 2016, in the Korean Intellectual Property Office, the disclosure of which is incorporated herein in its entirety by reference.

### BACKGROUND

The inventive concepts relate to methods of forming a tungsten film, and/or methods of fabricating a semiconductor device using the tungsten film. More particularly, the inventive concepts relate to methods of forming a tungsten film with reduced film stress, reduced impurity concentration, and/or reduced surface roughness, and/or methods of fabricating a semiconductor device using the same.

As integration of semiconductor devices increase, an area for a memory cell of the semiconductor devices may be reduced. Thus, techniques for reducing line-width of, for example, a metal wire are being continuously researched. To reduce line width of the metal wire, forming a contact plug exhibiting improved step coverage inside a contact hole, which has a high aspect ratio, is desired. Recently, a tungsten film may be formed to have improved step coverage in the contact hole using a chemical vapor deposition (CVD) method. Thus, a tungsten film may be often formed using a CVD method in a semiconductor device fabrication process. The tungsten film may be used as, for example, a metal wire, a via, a contact plug, and/or a buried word line.

### SUMMARY

The inventive concepts provide methods of forming a tungsten film with reduced film stress, reduced impurity concentration, and/or reduced surface roughness.

The inventive concepts also provide methods of fabricating a semiconductor device by using a tungsten film with reduced film stress, reduced impurity concentration, and/or reduced surface roughness.

According to an example embodiment of the inventive concepts, a method of forming a tungsten film may include disposing a substrate inside a process chamber, performing a tungsten nucleation layer forming operation for forming a tungsten nucleation layer on the substrate, performing a first operation for forming a portion of a tungsten bulk layer on the tungsten nucleation layer by alternately supplying a tungsten-containing gas and a reducing gas into the process chamber, and performing a second operation for stopping the supply of the tungsten-containing gas and the reducing gas and removing a remaining gas in the process chamber. The first operation and the second operation may be repeated at least twice until the tungsten bulk layer reaches a target thickness.

According to an example embodiment of the inventive concepts, a method of fabricating a semiconductor device may include forming a plurality of concave-convex patterns on a substrate, forming an insulation film on the plurality of concave-convex patterns, disposing the substrate including the plurality of concave-convex and the insulation film inside a process chamber, performing a tungsten nucleation layer forming operation for forming a tungsten nucleation layer on the insulation film, performing a first operation for forming a portion of a tungsten bulk layer on the tungsten nucleation layer by alternately supplying a tungsten-containing gas and a reducing gas into the process chamber, and performing a second operation for stopping the supply of the tungsten-containing gas and the reducing gas and removing a remaining gas in the process chamber. A tungsten film that fully covers the plurality of concave-convex patterns may be formed by repeatedly performing the first operation and the second operation two or more, until the tungsten bulk layer reaches a target thickness.

According to an example embodiment of the inventive concepts, a method of forming a tungsten film may include disposing a substrate in a process chamber, performing a SiH₄ based reduction reaction with regard to a tungsten containing gas to form a tungsten nucleation layer on the substrate, performing a H₂ based reduction reaction with regard to the tungsten-containing gas to form a tungsten bulk layer on the tungsten nucleation layer, and stopping supply of the tungsten-containing gas and H₂ gas, and removing a remaining gas in the process chamber. The performing a H₂ based reduction reaction and the stopping and removing may be repeated until the tungsten bulk layer reaches a target thickness

### BRIEF DESCRIPTION OF THE DRAWINGS

Example embodiments of the inventive concepts will be more clearly understood from the following detailed description taken in conjunction with the accompanying drawings in which:

FIG. 1 is a sectional view of a process chamber that may be used in a method of forming a tungsten film and a method of fabricating a semiconductor device, according to an example embodiment of the inventive concepts;

FIGS. 2A through 2D are gas flow diagrams for forming a tungsten film, according to an example embodiment;

FIG. 3 is a process flowchart for describing a method of forming a tungsten film according to an example embodiment;

FIGS. 4A through 4D are cross-sectional views for describing a method of forming a tungsten film, according to an example embodiment;

FIGS. 5A and 5B are cross-sectional views for describing a difference between a tungsten film fabricated according to an example embodiment and a tungsten film fabricated according to a comparative embodiment;

FIG. 6 is a schematic plan view of a cell array region of a semiconductor device fabricated according to an example embodiment;

FIGS. 7A through 7E are cross-sectional views for describing a method of fabricating a semiconductor device, taken along a line VII-VII′ of FIG. 6, according to an example embodiment;

FIG. 8 is a schematic diagram showing a card including a semiconductor device fabricated according to an example embodiment;

### DETAILED DESCRIPTION

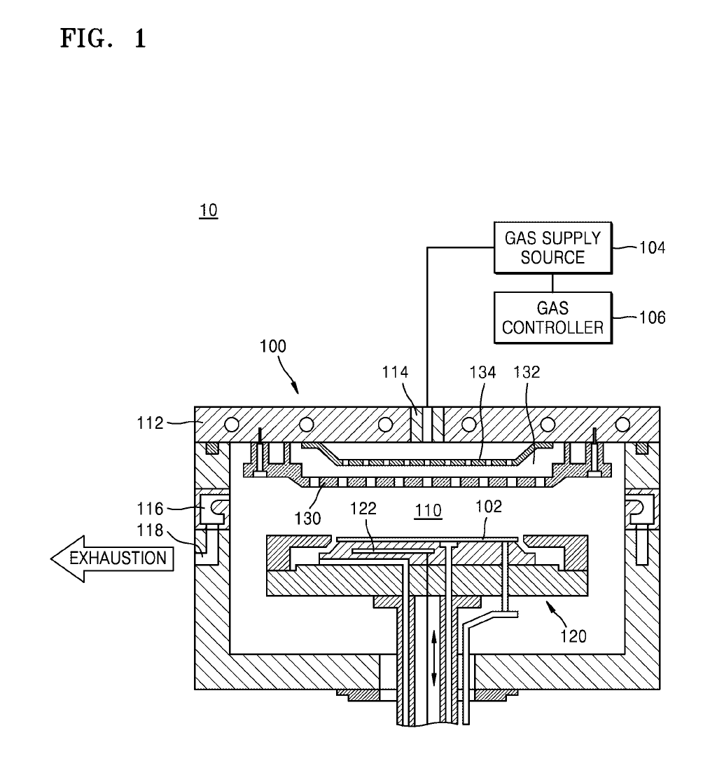

FIG. 1 is a sectional view of a process chamber that may be used in a method of forming a tungsten film and a method of fabricating a semiconductor device, according to an example embodiment of the inventive concepts.

FIG. 1 is a schematic sectional view of a process chamber 100 that may be used in a chemical vapour deposition (CVD) method for forming a tungsten film on a substrate supporting element 120.

The process chamber 100 may be a portion of a semiconductor device manufacturing apparatus 10 including a plurality of process chambers. The process chamber 100 may include an interior 110 defined by sidewalls, a bottom, and a cover 112 of the process chamber 100. The sidewalls and the bottom are integrally formed by using a single aluminum block. The sidewall may include a conduit (not shown), through which a fluid for controlling the temperature of the sidewall may flow. Furthermore, the process chamber 100 may include a pumping ring 116 that connects the interior 110 of the process chamber 100 to an exhaustion port 118.

A substrate supporting element 120, which is capable of controlling temperature thereof, may be disposed near the center of the interior 110 of the process chamber 100. The substrate supporting element 120 supports a substrate 102 during formation of a tungsten film. For example, the substrate supporting element 120 may include aluminum, ceramic, or a combination of aluminium and ceramic. Further, the substrate supporting element 120 may include a vacuum port (not shown) and/or one or more heating elements 122.

Vacuum may be applied between the substrate 102 and the substrate supporting element 120 by the vacuum port, thereby attaching the substrate 102 to the substrate supporting element 120 during formation of a tungsten film. The heating element 122 may be disposed inside the substrate supporting element 120 and may be configure to heat the substrate supporting element 120 and the substrate 102 disposed thereon to a certain temperature.

The cover 112 may be supported by the sidewalls and may be detached from the sidewalls for maintenance of the process chamber 100. For example, the cover 112 may include aluminium. Further, the cover 112 may include a conduit therein, through which a fluid for controlling the temperature of the cover 112 may flow.

A mixing block 114 may be disposed inside the cover 112. The mixing block 114 may be connected to a gas supply source 104. For example, individual gases supplied by the gas supply source 104 may be mixed with one another inside the mixing block 114. The gases may be mixed to a single homogenous gas flow inside the mixing block 114, and the single homogenous gas flow may be supplied to the interior 110 of the process chamber 100 via a shower head 130.

The shower head 130 may be connected to the cover 112. Furthermore, a porous blocker plate 134 may be selectively disposed in an area 132 inside the shower head 130, which is defined by the shower head 130 and the cover 112. Via the mixing block 114, a gas to be supplied to the interior 110 of the process chamber 100 may be first diffused by the porous blocker plate 134. Next, the gas may be supplied to the interior 110 of the process chamber 100 via the shower head 130. The porous blocker plate 134 and the shower head 130 may be configured to provide a uniform gas flow to the interior 110 of the process chamber 100. A uniform gas flow may accelerate formation of a uniform tungsten film on the substrate 102.

A gas line for supplying a process gas or gases (e.g., a tungsten-containing gas and/or a reducing gas) from the gas supply source 104 to the interior 110 of the process chamber 100 may include a valve (not shown) for switching gas flows.

Furthermore, the gas supply source 104 may be controlled by a gas controller 106. In other words, the gas controller 106 may control the gas supply source 104, thereby controlling a type of a gas supplied to the interior 110 of the process chamber 100, time points for starting and stopping gas supply, and/or flux of a gas.

An example embodiment for forming a tungsten film by supplying a gas into the process chamber 100 will be described below.

First, the substrate 102 may be introduced into the process chamber 100, and the substrate 102 may be mounted on the substrate supporting element 120. The substrate 102 may include a plurality of concave-convex patterns and an insulation film formed on the plurality of concave-convex patterns.

Next, under the control of the gas controller 106, a certain amount of a process gas may be supplied from the gas supply source 104 to the mixing block 114, and the process gas may be supplied to the interior 110 of the process chamber 100 in a substantially uniform manner.

At the same time, the interior 110 of the process chamber 100 may be maintained at a certain pressure by exhausting the atmosphere inside the interior 110 of the process chamber 100 via the exhaustion port 118, and the heating element 122 in the substrate supporting element 120 may be driven to emit heat energy.

The emitted heat energy may heat the upper portion of the substrate supporting element 120 and may heat the substrate 102 mounted on the substrate supporting element 120 to a certain temperature. The supplied process gas may start a chemical reaction, and thus a tungsten film may be formed on the top surface of the substrate 102.

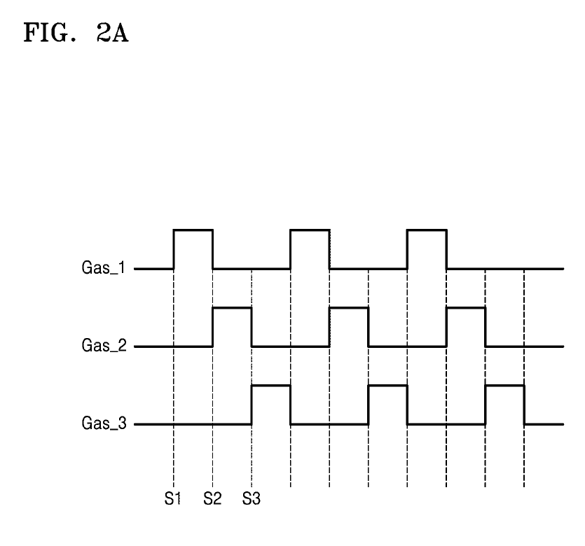

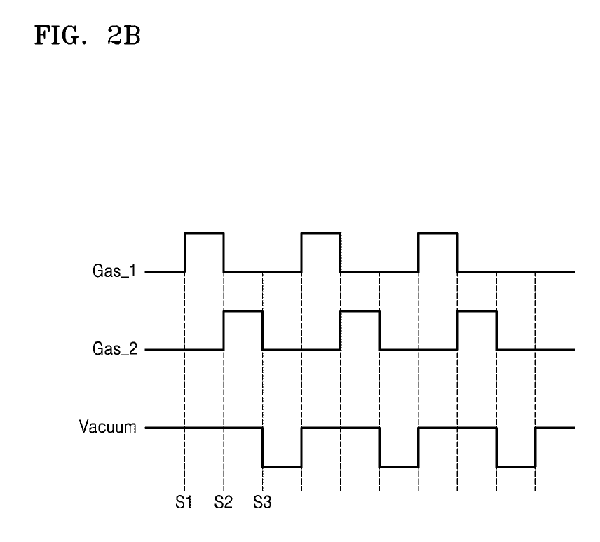

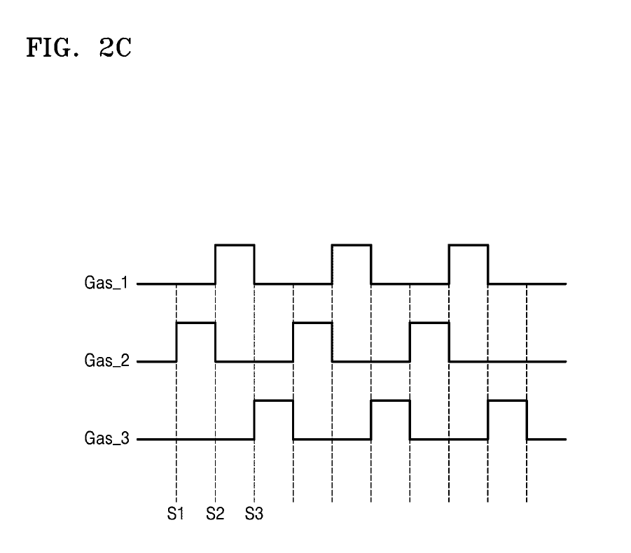

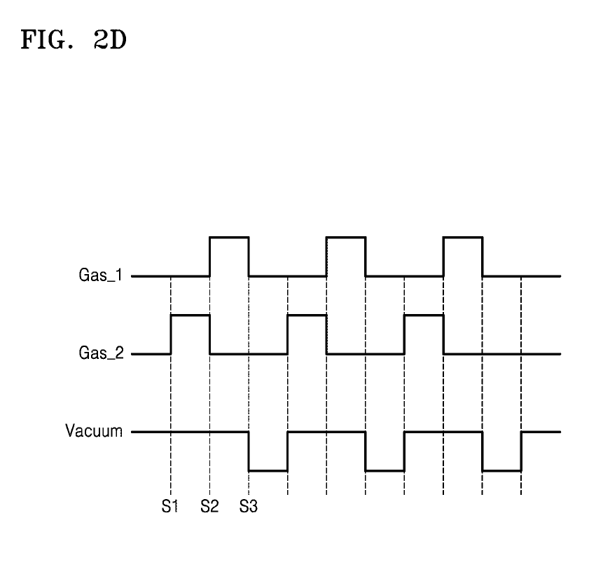

FIGS. 2A through 2D are gas flow diagrams for forming a tungsten film, according to an example embodiment.

Referring to FIGS. 2A and 2D, respective process gases flowing into the process chamber 100 (refer to FIG. 1) will be described in detail. FIGS. 2A through 2D show supplying 3 different types of process gases and/or vacuum atmosphere. Each process gas will be described below in detail.

A tungsten-containing gas may include at least one of WF₆ gas or organic tungsten source gas. A reducing gas may include at least one selected from among hydrogen (H₂), silane (SiH₄), disilane (Si₂H₆), dichlorosilane (SiH₂Cl₂), diborane (B₂H₆), and phosphine (PH₃). A purge gas may include an inert gas (e.g., argon (Ar) and nitrogen (N₂)).

Flows of process gases and vacuum exhaustion are shown according to lapse of time. The flows of process gases are illustrated to protrude upward when the pressure inside the process chamber 100 (refer to FIG. 1) increases due to supply of process gases, and the flow of vacuum exhaustion is illustrated to protrude downward when the pressure inside the process chamber 100 (refer to FIG. 1) decreases.

Referring to FIG. 2A, a first gas supply operation Gas_1 illustrates a gas flow diagram for supplying the tungsten-containing gas, a second gas supply operation Gas_2 illustrates a gas flow diagram for supplying the reducing gas, and a third gas supply operation Gas_3 illustrates a gas flow diagram for supplying the purge gas.

Here, the first gas supply operation Gas_1 and the second gas supply operation Gas_2 for forming a tungsten film may be referred to as a first operation, whereas the third gas supply operation Gas_3 for removing remaining gases in the process chamber 100 (refer to FIG. 1) may be referred to as a second operation. According to an example embodiment, a tungsten film having a desired thickness may be formed by repeatedly performing the first operation and the second operation at least twice.

In other words, an operation for forming a tungsten bulk layer may be performed by alternately supplying the tungsten-containing gas and the reducing gas, stopping supply of the tungsten-containing gas and the reducing gas, and supplying the purge gas. Furthermore, the operation for forming a tungsten bulk layer may be terminated after the purge gas is supplied.

A supply start time S1 regarding the first gas supply operation Gas_1, a supply start time S2 regarding the second gas supply operation Gas_2, and a supply start time S3 regarding the third gas supply operation Gas_3 may be different from one another. In order to alternately supply the tungsten-containing gas and the reducing gas, the supply start time S2 regarding the second gas supply operation Gas_2 may be substantially identical to a supply end time regarding the first gas supply operation Gas_1. Furthermore, in order to stop supplying the tungsten-containing gas and the reducing gas and to supply the purge gas, the supply start time S3 regarding the third gas supply operation Gas_3 may be substantially identical to a supply end time regarding the second gas supply operation Gas_2.

Although not shown, there may be intervals between gas supply operations. For example, the supply start time S2 regarding the second gas supply operation Gas_2 may be different from the supply end time regarding the first gas supply operation Gas_1, and the supply start time S3 regarding the third gas supply operation Gas_3 may be different from the supply end time regarding the second gas supply operation Gas_2. Periods and numbers of intervals may be selected such that the process chamber 100 is maintained in a desired state for formation of a tungsten film.

When a period from a supply start time S1 regarding the first gas supply operation Gas_1 to a next supply start time S1 regarding the first gas supply operation Gas_1 in an operation for forming a tungsten film may be referred to as one cycle, FIG. 2A shows that 3 cycles are performed. However, the number of the cycles is not limited.

Here, the period of each of the first gas supply operation Gas_1 and the second gas supply operation Gas_2 may be from 1 second to 30 seconds, whereas the period of the third gas supply operation Gas_3 may be from 0.1 seconds to 30 seconds. Periods of the gas supply operations may be identical to or different from one another. The periods of the gas supply operations may vary depending on a desired thickness or a desired characteristic of a tungsten film, and thus are not limited.

The overall pressure of the tungsten-containing gas, the reducing gas, and the purge gas may be controlled to be constant via the first gas supply operation Gas_1, the second gas supply operation Gas_2, and the third gas supply operation Gas_3. By maintaining the overall pressure of the process gases constant, the temperature of the substrate 102 (refer to FIG. 1) and/or absorption amounts of gases deposited on the substrate 102 (refer to FIG. 1) may be maintained to be constant.

The overall pressure of the process gases may be controlled by measuring the pressure of the interior 110 of the process chamber 100 (refer to FIG. 1) using a vacuum meter (not shown) connected to the process chamber 100 (refer to FIG. 1) and adjusting the exhaustion port 118 (refer to FIG. 1) to control the measured pressure to be constant.

Referring to FIG. 2B, the first gas supply operation Gas_1 illustrates a gas flow diagram for supplying the tungsten-containing gas, the second gas supply operation Gas_2 illustrates a gas flow diagram for supplying the reducing gas, and a vacuum exhausting operation Vacuum illustrates a flow diagram for performing vacuum exhaustion. When the first gas supply operation Gas_1 and the second gas supply operation Gas_2 is referred to as a first operation, and the vacuum exhausting operation Vacuum is referred to as a second operation, a purge operation may be performed via vacuum exhaustion in the second operation. Thus, instead of removing remaining gases by injecting an inert gas into the process chamber 100 (refer to FIG. 1), the remaining gas may be removed by performing vacuum exhaustion via the exhaustion port 118 (refer to FIG. 1). In some example embodiments, vacuum exhaustion may be performed simultaneously or concurrently as a purge gas is supplied into the process chamber 100 (refer to FIG. 1).

In order to stop supplying the tungsten-containing gas and the reducing gas and start vacuum exhaustion, a vacuum start time S3 regarding the vacuum exhausting operation Vacuum may be substantially identical to the supply end time regarding the second gas supply operation Gas_2. Descriptions identical to those given above with reference to FIG. 2A are omitted.

Referring to FIGS. 2C and 2D, during the first operation, the second gas supply operation Gas_2 may be performed first, and then the first gas supply operation Gas_1 may be performed.

For example, the reducing gas may be supplied first, and after the supply of the reducing gas is terminated, the tungsten-containing gas may be supplied.

In order to alternately supply the tungsten-containing gas and the reducing gas, the supply end time S2 regarding the second gas supply operation Gas_2 may be substantially identical to a supply start time regarding the first gas supply operation Gas_1. Furthermore, in order to stop supplying the tungsten-containing gas and the reducing gas and to supply the purge gas or start vacuum exhaustion, the supply start time S3 regarding the third gas supply operation Gas_3 or the vacuum start time S3 regarding the vacuum exhausting operation Vacuum may be substantially identical to a supply end time regarding the first gas supply operation Gas_1. Descriptions identical to those given above with reference to FIGS. 2A and 2B are omitted.

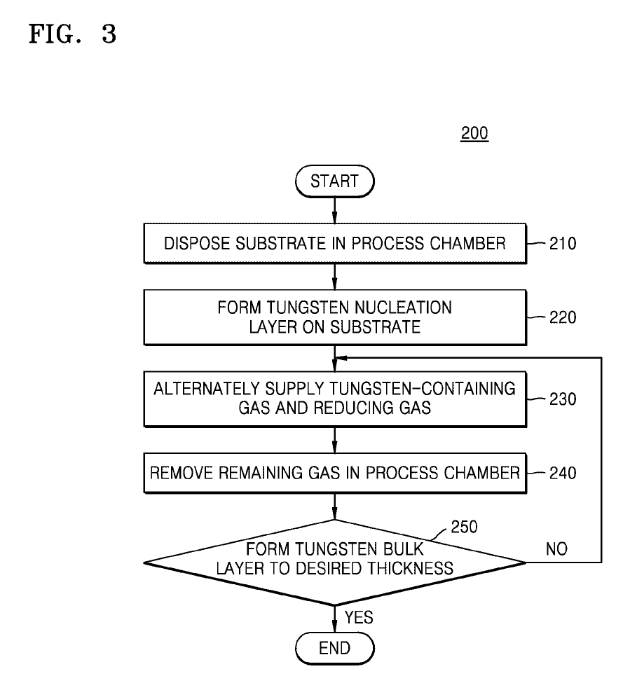

FIG. 3 is a process flowchart for describing a method of forming a tungsten film, according to an example embodiment.

Referring to FIG. 3, the method may include a first operation 210 for disposing a substrate inside a process chamber, a second operation 220 for forming a tungsten nucleation layer on the substrate, a third operation 230 for alternately supplying a tungsten-containing gas and a reducing gas, a fourth operation 240 for removing a remaining gas in the process chamber, and a fifth operation 250 for determining whether a tungsten bulk layer is formed to a desired thickness.

In the first operation 210, a process substrate may be loaded into the process chamber 100 (refer to FIG. 1), in which a tungsten film is to be formed by adjusting process conditions. A plurality of concave-convex patterns may be formed on the substrate and an insulation film may be formed on the plurality of concave-convex patterns.

In the second operation 220, a tungsten nucleation layer may be first formed on the substrate. The tungsten nucleation layer may be a thin tungsten film that functions as a growth site for a tungsten bulk layer to be formed later. The tungsten nucleation layer may be formed via a chemical vapor deposition according to an example embodiment. A process for forming the tungsten nucleation layer may be performed inside the process chamber 100 (refer to FIG. 1) as described above.

The tungsten nucleation layer may include, for example, tungsten, a tungsten alloy, a tungsten-containing material (e.g., tungsten boride or tungsten silicide), and a combination thereof. For example, the tungsten nucleation layer may be formed to have a thickness from about 10Å to about 200Å, but is not limited thereto.

In some example embodiments, a reducing gas including hydrogen (H₂) and/or argon (Ar) may be supplied into the process chamber 100 (refer to FIG. 1) after the second operation 220 is performed, thereby removing a remaining tungsten-containing precursor or byproduct from the second operation 220.

In the third operation 230, the tungsten-containing gas and the reducing gas may be alternately supplied into the process chamber 100 (refer to FIG. 1). As described above, the tungsten-containing gas and the reducing gas may be supplied in various orders as illustrated in FIGS. 2A to 2D. As the tungsten-containing gas and the reducing gas are supplied, a portion of a tungsten bulk layer may be formed on the substrate. The tungsten bulk layer may be formed in the Frank-van der Merwe (FM) mode. In other words, the tungsten bulk layer may be formed layer-by-layer. As a result, the tungsten bulk layer may be formed to have a thickness from about 40Å to about 100Å.

The tungsten bulk layer may be formed on the tungsten nucleation layer formed in the second operation 220. The formation of the tungsten bulk layer may be performed in the same process chamber in which the tungsten nucleation layer is formed. According to some example embodiments the tungsten nucleation layer may be formed in an atomic layer deposition (ALD) process chamber, whereas the tungsten bulk layer may be formed in a CVD process chamber.

Throughout the specification, the term ‘pulse’ refers to intermittent or non-continuous supply of a process gas to the interior 110 of the process chamber 100 (refer to FIG. 1).

An amount of a process gas at each pulse depends on period of the corresponding pulse and will vary according to the period. Period of each pulse may vary based on various factors including volume capacity of a process chamber being used, vacuum system, and/or volatility of a process gas.

During the formation of the tungsten bulk layer, the process pressure inside the process chamber 100 (refer to FIG. 1) may be set from about 10 Torr to about 40 Torr, and the process temperature may be set from about 300° C. to about 400° C. Furthermore, the process pressure and/or the process temperature in the third operation 230 may be higher than the process pressure and/or the process temperature in the second operation 220. For example, the higher the process pressure and/or the process temperature is/are, the faster a tungsten film grows.

In the fourth operation 240, in order to stop supplying the tungsten-containing gas and the reducing gas and to remove remaining gases in the process chamber 100 (refer to FIG. 1), the purge gas may be supplied and/or vacuum exhaustion may be performed. As described above, the start time regarding the fourth operation 240 may be substantially identical to the supply end time regarding the third operation 230. A period for performing the third operation 230 and the fourth operation 240 once may be referred to as a single cycle.

In the remaining gases, a fluorine impurity may be an element affecting tungsten film stress. Therefore, the fourth operation 240 may be performed to remove the fluorine impurity.

In the fifth operation 250, whether the formed tungsten bulk layer has a desired thickness may be determined. If the tungsten bulk layer has the desired thickness, the operations for forming the tungsten film may be terminated. If not, the third operation 230 and the fourth operation 240 may be repeated.

As described above, a portion of a tungsten bulk layer having a certain thickness may be formed after one cycle is performed. A tungsten bulk layer having a thickness from about 40Å to about 100Å may be formed in one cycle. In some example embodiments, another cycle may be desired to form additional tungsten bulk layer to form a resultant structure of tungsten bulk layers having a desired thickness.

For example, in order to form a tungsten bulk layer having a target thickness of about 400Å, four cycles at a formation rate of about 100Å per cycle may be performed. In this case, the third operation 230 and the fourth operation 240 may be repeated four times until the desired thickness of the tungsten bulk layer is obtained.

While the tungsten bulk layer is formed to a desired thickness in the above-stated operations, a mixture ratio between the tungsten-containing gas and the reducing gas may be adjusted to reduce an amount of a fluorine impurity in the tungsten bulk layer. Furthermore, the mixture ratio between the tungsten-containing gas and the reducing gas may be adjusted to reduce film stress and surface roughness of the tungsten bulk layer.

The third operation 230 and the fourth operation 240 may be repeated until the plurality of concave-convex patterns, such as contact plugs and vias, formed on the substrate are filled with tungsten films. When a tungsten bulk layer reaches a desired thickness, the operation for forming the tungsten film may be terminated.

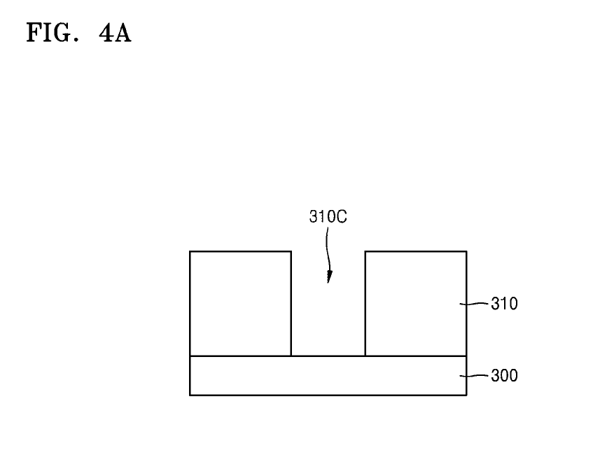

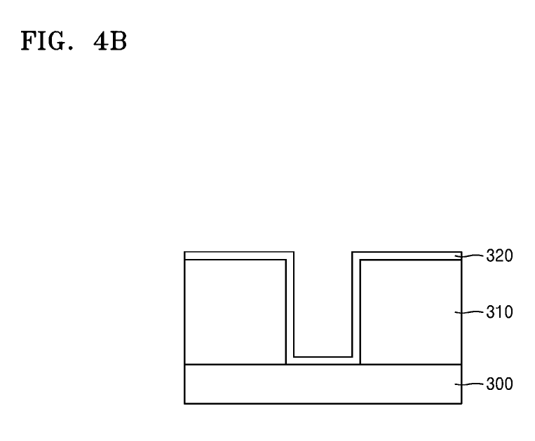

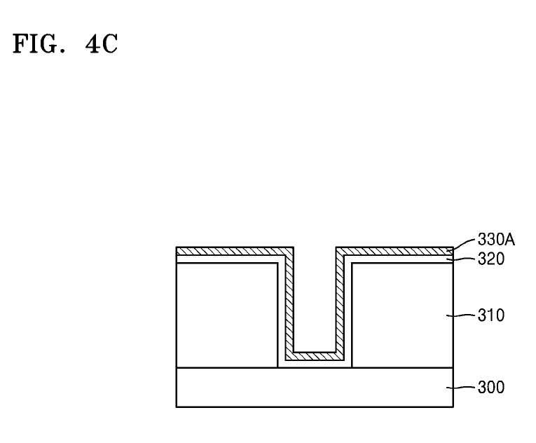

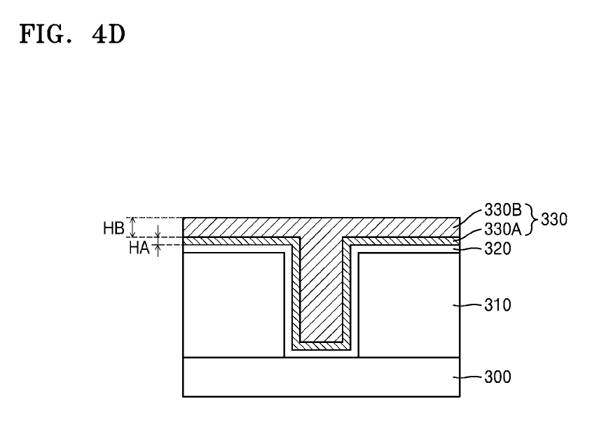

FIGS. 4A through 4D are cross-sectional views for describing a method of forming a tungsten film according to an example embodiment.

Referring to FIG. 4A, after an insulation film is formed on a substrate 300, a photolithography operation and an etching operation may be performed by using a mask (not shown) so that an insulation film pattern 310 including a contact hole 310C is formed and a portion of the substrate 300 is exposed through the contact hole 310C.

Referring to FIG. 4B, a diffusion barrier film 320 may be formed on the top surface of the insulation film pattern 310, sides of the contact hole 310C, and the exposed top surface of the substrate 300. The diffusion barrier film 320 may include Ti and TiN to mitigate or prevent tungsten from being diffused.

Referring to FIG. 4C, a tungsten nucleation layer forming operation according to the example embodiment as described above with reference to FIG. 3 may be performed, thereby forming a tungsten nucleation layer 330A on the top surface of the diffusion barrier film 320. The tungsten nucleation layer 330A forming operation may perform an operation for forming a portion of the tungsten nucleation layer 330A and an operation for purging a process chamber at least two times. Thus, the tungsten nucleation layer 330A having a desired thickness may be formed.

Referring to FIG. 4D, a tungsten bulk layer 330B may be formed on the tungsten nucleation layer 330A until the contact hole 310C (refer to FIG. 4A) is filled by performing an operation for forming a tungsten bulk layer and a purging operation as described above with reference to FIG. 3. Here, the process pressure inside the process chamber may be from about 10 Torr to about 40 Torr, and the process temperature inside the process chamber may be from about 300° C. to about 400° C. A tungsten bulk layer having a thickness from about 40Å to about 100Å may be formed in a single operation for forming a tungsten bulk layer, and thus the operation for forming a tungsten bulk layer having a desired thickness may be formed by repeating the operation for forming a tungsten bulk layer two or more times. As a result, a tungsten film 330 having a desired thickness is formed. According to an example embodiment, a reaction formula regarding the tungsten film 330 may be as shown below.

[Reaction Formula]

First Stage:

2WF₆(g)+3SiH₄(g)→2W(s)+3SiF₄(g)+6H₂(g)

Second Stage:

WF₆(g)+3H₂(g)→W(s)+6HF(g)

The first stage is a reaction for forming a tungsten nucleation layer by using SiH₄ reduction reaction, and the second stage is a reaction for forming a tungsten bulk layer by using H₂ reduction reaction.

Here, because the first stage reaction exhibits higher reactivity than the second stage reaction, forming a tungsten film in the first stage reaction is easier than forming a tungsten film in the second reaction. However, due to relatively poor step coverage of the tungsten film formed during the first stage reaction, the diameter of the upper portion of a contact hole may be reduced. Thus, to improve step coverage of the tungsten film, after the tungsten nucleation layer 330A having a relatively small thickness HA is formed in the first stage, the tungsten bulk layer 330B having a relatively large thickness HB may be formed in the second stage.

According to an example embodiment, by using a CVD method in which an operation for forming a tungsten bulk layer and an operation for removing a remaining gas are alternately performed, a tungsten film with reduced film stress, reduced impurity concentration, and/or enhanced surface roughness may be obtained, and an excellent semiconductor device may be fabricated by using the same.

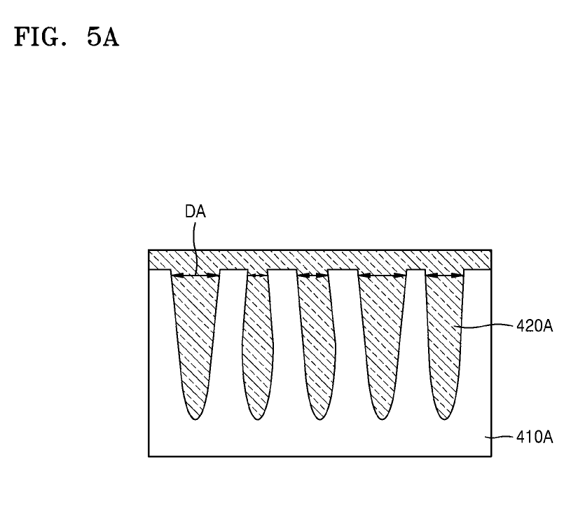

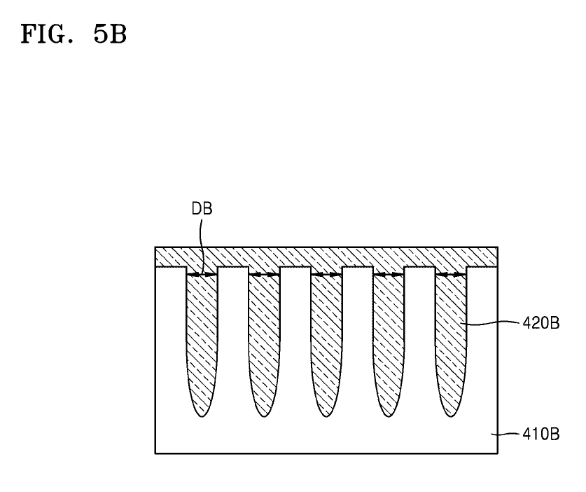

FIGS. 5A and 5B are cross-sectional views for describing a difference between a tungsten film fabricated according to an example embodiment and a tungsten film fabricated according to a comparative embodiment.

Referring to FIG. 5A, the tungsten film according to the comparative embodiment is shown. The tungsten film according to the comparative embodiment may be formed by continuously supplying a tungsten-containing gas and/or a reducing gas. A tungsten film 420A may be formed by continuously supplying the tungsten-containing gas and the reducing gas onto a material film 410A on which a plurality of concave-convex patterns are formed.

Along with integration of semiconductor devices, critical dimensions (CD) of metal wires, vias, and contact plugs having tungsten films deposited thereon become narrower. CD reductions may cause unexpected defects during formation of a tungsten film. One of the most common defects is bending of a pattern due to stress of a tungsten film as shown in FIG. 5A. Due to the bending of the pattern, distribution of diameters DA of an opening portion of the pattern increases. The increased distribution of diameters DA may cause a reduced margin, a defective connection, and/or a deteriorated performance of a semiconductor device in a later semiconductor device fabricating operation. Therefore, stress of a tungsten film is desired to be reduced to mitigate bending of a pattern.

Referring to FIG. 5B, a tungsten film 420B fabricated according to a method of forming a tungsten film according to an example embodiment is shown.

As described above, in order to form the tungsten film 420B, a tungsten bulk layer is formed by performing operations for supplying a pulse-type tungsten-containing gas and a reducing gas and a purging operation. In case of forming the tungsten film 420B on a material film 410B, on which a plurality of concave-convex patterns are formed (e.g., in the case of forming the tungsten film 420B on a pattern having the largest diameter DB of an opening portion of the pattern of about 35 nm, the pitch of about 45 nm, and the aspect ratio of 1:50), distribution of diameters DB of the opening portion due to film stress may be about 3 sigma. In other words, compared to the distribution of the diameters DA (refer to FIG. 5A) of the comparative embodiment, distribution of the diameters DB can be reduced by 10% or more.

Therefore, according to an example embodiment, by using a CVD method in which an operation for forming a tungsten bulk layer and an operation for removing a remaining gas are alternately performed, a tungsten film with reduced film stress and reduced distribution of diameters of an opening portion due to the reduced film stress may be obtained. Thus, an excellent semiconductor device may be fabricated by using the same.

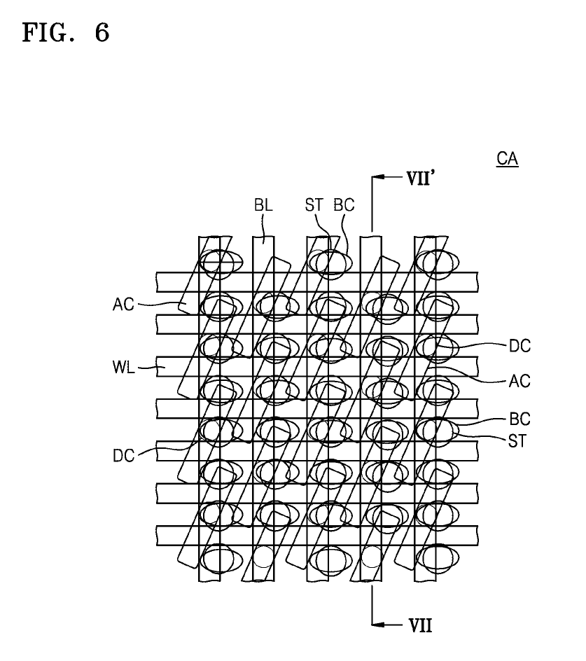

FIG. 6 is a schematic plan view of a cell array region of a semiconductor device fabricated according to an example embodiment.

Referring to FIG. 6, the semiconductor device may include a plurality of active regions AC. A plurality of word lines WL may extend across the plurality of active regions AC and extend in a first direction in parallel to one another. The plurality of word lines WL may be arranged at a constant interval. A plurality of bit lines BL extend in a second direction, which is perpendicular to the first direction, in parallel to one another over the plurality of word lines WL.

The plurality of bit lines BL may be connected to the plurality of active regions AC via a plurality of direct contacts DC, respectively.

According to some example embodiments, the plurality of bit lines BL may be arranged in parallel to each other at a pitch of 3F. According to some other example embodiments, the plurality of word lines WL may be arranged in parallel to each other at a pitch of 2F.

Each of a plurality of buried contacts BC may include a contact structure that extends from a region between two bit lines BL adjacent to each other from among the plurality of bit lines BL onto the top of either of the two bit lines BL adjacent to each other. According to some example embodiments, the plurality of buried contacts BC may be linearly arranged in the first direction and the second direction. According to some example embodiments, the plurality of buried contacts BC may be arranged in the second direction at a constant interval. The plurality of buried contacts BC may electrically connect bottom electrodes ST of capacitors to the active regions AC.

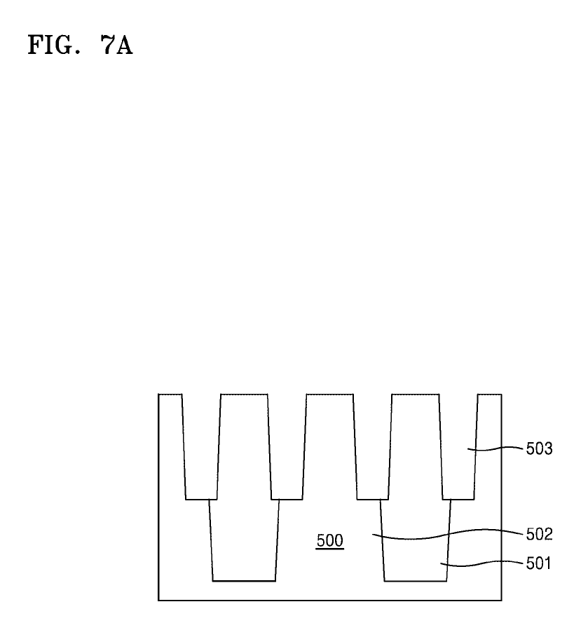

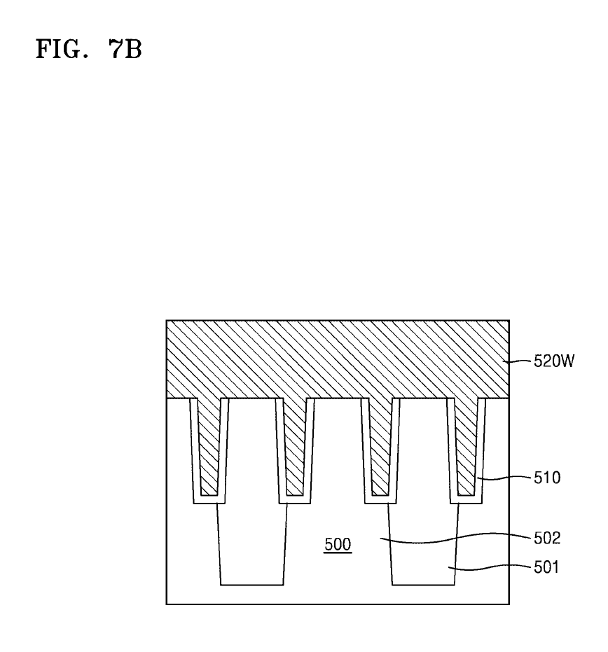

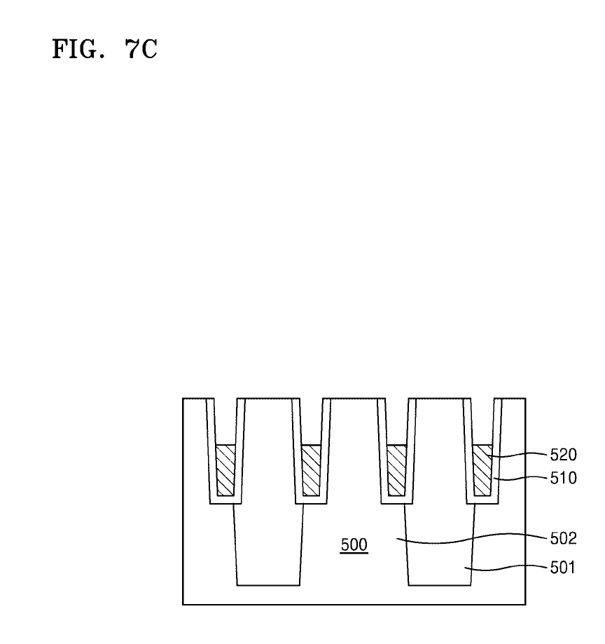

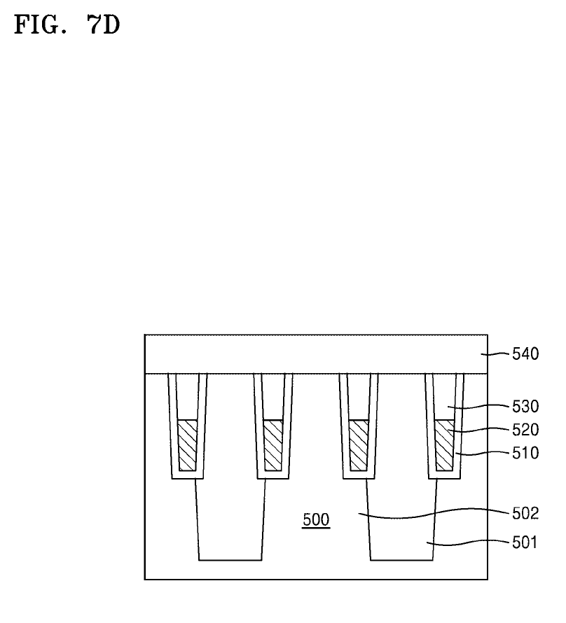

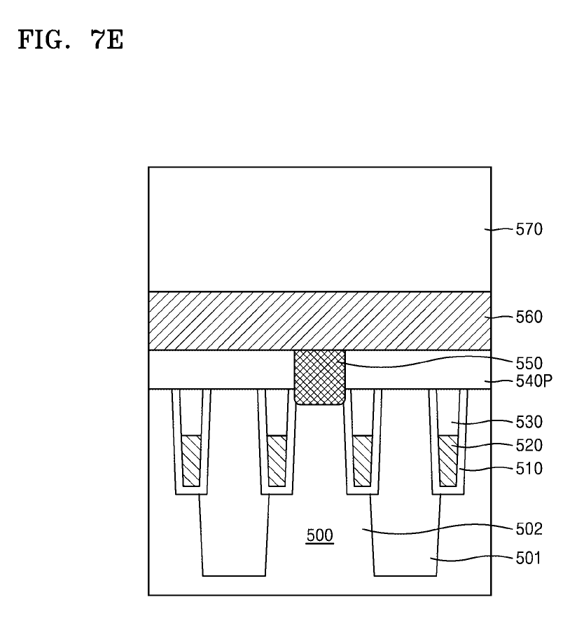

FIGS. 7A through 7E are cross-sectional views for describing a method of fabricating a semiconductor device according to an example embodiment.

A cell array region of the semiconductor device may have a layout CA as illustrated in in FIG. 6. FIGS. 7A through 7E are cross-sectional views of a portion, obtained along a line VII-VII′ of FIG. 6.

Referring to FIG. 7A, a device isolation film 501 defining an active area 502 of a substrate 500 may be formed. The device isolation film 501 may be a shallow trench isolation (STI) film for improving speed and integration of the semiconductor device, but is not limited thereto.

Next, a trench 503 for forming a recess channel may be formed in the active area 502 defined by the device isolation film 501. The trench 503 may be formed to have a width from about 10 nm to about 100 nm.

One or more recess channels may be formed, and thus the plurality of trenches 503 may be formed in the active area 502 defined by the device isolation film 501. Furthermore, in order to form the trench 503, a buffer insulation film such as a silicon oxide film may be formed on the top surface of the substrate 500, and a hard mask such as a polysilicon layer or a silicon nitride film may be formed thereon. Because the above-stated components are known in the art, detailed description thereof is omitted.

The substrate 500 may include silicon (Si) (e.g., crystalline Si, poly-Si, or amorphous Si). According to some example embodiments, the substrate 500 may include a semiconductor material (e.g., germanium (Ge), silicon germanium (SiGe), silicon carbide (SiC), gallium arsenide (GaAs), indium arsenide (InAs), or indium phosphide (InP)). According to some example embodiments, the substrate 500 may include a conductive region(e.g., a well doped with an impurity or a structure doped with an impurity).

Referring to FIG. 7B, a gate insulation film 510 may be formed on surfaces of the trench 503 (more specifically, on the bottom surface and side surfaces of the trench 503). The gate insulation film 510 may be a thermal oxide film formed in a thermal oxidizing operation. In order to form the gate insulation film 510, a thermal oxide film formed on the top surface of the substrate 500 may be removed by a technique well known in the art (e.g., etching). Detailed description thereof is omitted. A word line forming film 520W may be formed on the entire gate insulation film 510 and the top surface of the substrate 500.

The gate insulation film 510 may include at least one of a silicon oxide film, a silicon nitride film, a silicon oxynitride film, an oxide/nitride/oxide (ONO) film, or a high-k dielectric film having a higher dielectric constant than a silicon oxide film. For example, the gate insulation film 510 may have a higher dielectric constant from about 10 to about 25. According to some example embodiments, the gate insulation film 510 includes at least one material selected from among hafnium oxide (HfO), hafnium silicate (HfSiO), hafnium oxynitride (HfON), hafnium silicon oxiynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), or lead scandium tantalum oxide (PbScTaO). For example, the gate insulation film 510 may include HfO₂, Al₂O₃, HfAlO₃, Ta₂O₃, or TiO₂.

The word line forming film 520W may be formed according to the method of forming a tungsten film according to the above-stated example embodiment. For example, a tungsten nucleation layer may be formed first, and an operation for forming a tungsten bulk layer and a purging operation may be alternately performed onto the tungsten nucleation layer, thereby forming the tungsten bulk layer until the trench 503 (refer to FIG. 7A) is completely filled with the tungsten bulk layer. Here, the process pressure inside the process chamber may be from about 10 Torr to about 40 Torr, and the process temperature inside the process chamber may be from about 300° C. to about 400° C. A tungsten bulk layer having a thickness from about 40Å to about 100Å may be formed in a single operation for forming a tungsten bulk layer.

Thus, the operation for forming a tungsten bulk layer may be repeated two or more times to form the word line forming film 520W having a desired thickness.

Referring to FIG. 7C, in a semiconductor device like a buried cell array transistor (BCAT), the gate insulation film 510 and buried word lines 520 may be formed to not protrude beyond uppermost surfaces of the substrate 500, and to be completely buried in the substrate 500.

The buried word lines 520 may be formed as described above. First, the word line forming film 520W (refer to FIG. 7B) may be formed on the substrate 500 to cover the trench 503 (refer to FIG. 7A). Next, the word line forming film 520W (refer to FIG. 7B) may be polished by using, for example, a chemical mechanical polishing (CMP) technique or an etchback technique to expose the top surface of the substrate 500. The buried word lines 520 may be formed by recessing the polished word line forming film 520W (refer to FIG. 7B) into the substrate 500 by, for example, partially etching the polished word line forming film 520W.

Referring to FIG. 7D, a capping film 530 may be formed on the gate insulation film 510 and/or the buried word lines 520. The capping film 530 is formed to not protrude beyond uppermost surfaces of the substrate 500. In other words, the capping film 530 may be formed to be completely buried in the substrate 500. In some example embodiments, the upper portion of the gate insulation film 510 may be recessed into the substrate 500, and the capping film 530 may be formed to cap both the upper portion of the gate insulation film 510 and the upper portions of the buried word lines 520. Furthermore, a top insulation film 540 may be formed on the top surface of the capping film 530 and the top surface of the substrate 500.

The top insulation film 540 may be formed to have a thickness from about 200Å to about 400Å. The top insulation film 540 may include a silicon oxide. For example, the top insulation film 540 may include tetraethylorthosilicate (TEOS), high density plasma (HDP), or boro-phospho silicate glass (BPSG).

Referring to FIG. 7E, a top insulation film pattern 540P may be formed by patterning the top insulation film 540 (refer to FIG. 7D) on the substrate 500. A direct contact 550, which may be electrically connected to a source region of the active area 502, may be formed by filling an opening formed in the top insulation film pattern 540P with a conductive material.

Bit lines 560 that extend in parallel to one another on the top insulation film pattern 540P and the direct contact 550 and insulation capping lines 570 that cover the top surfaces of the bit lines 560 may be formed. The bit line 560 may be electrically connected to the direct contact 550.

The bit line 560 may have a multilayered structure in which a first metal silicide film, a conductive barrier film, a second metal silicide film, and an electrode layer including a metal or a metal nitride are sequentially stacked. For example, the bit line 560 may have a stacked structure in which, for example a doped poly-silicon film, a TiN film, and a tungsten film are sequentially stacked. Here, the tungsten film may be formed according to a method of forming a tungsten film according to an example embodiment of the inventive concepts.

According to some example embodiments, the insulation capping line 570 may include a silicon nitride film. Thickness of the insulation capping line 570 may be greater than that of the bit line 560.

According to a method of fabricating a semiconductor device using a method of forming a tungsten film according to an example embodiment, a semiconductor device such as a BCAT (which exhibits improved characteristics) may be fabricated.

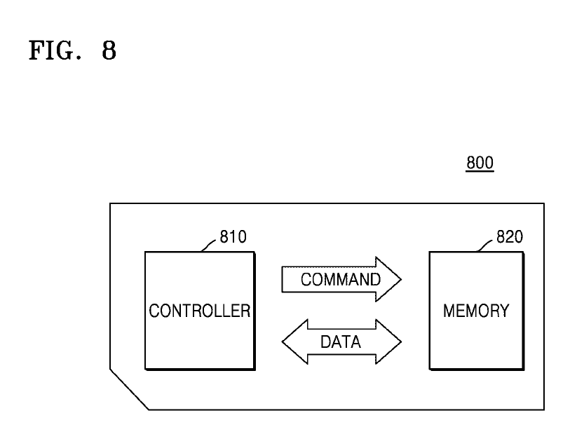

FIG. 8 is a schematic diagram showing a card 800 including a semiconductor device fabricated according to an example embodiment.

For example, in the card 800, a controller 810 and a memory 820 may be arranged to exchange electric signals with each other. For example, when the controller 810 issues a command, the memory 820 may transmit data. The memory 820 or the controller 810 may include a semiconductor device fabricated according to a method of fabricating a semiconductor device according to an example embodiment. The card 800 may be one of various types of cards, e.g., a memory stick card, a smart media (SM) card, a secure digital (SD) card, a mini SD card, or a multimedia card (MMC).

While the inventive concepts have been particularly shown and described with reference to some example embodiments thereof, it will be understood that various changes in form and details may be made therein without departing from the spirit and scope of the following claims.

What is claimed is:

1. A method of forming a tungsten film, the method comprising:
disposing a substrate inside a process chamber;
performing a tungsten nucleation layer forming operation for forming a tungsten nucleation layer on the substrate;
performing a first operation for forming a portion of a tungsten bulk layer on the tungsten nucleation layer by alternately supplying a tungsten-containing gas and a reducing gas into the process chamber; and
performing a second operation for stopping the supply of the tungsten-containing gas and the reducing gas and removing a remaining gas in the process chamber,
wherein the first operation and the second operation are repeated at least twice until the tungsten bulk layer reaches a target thickness.

2. The method of claim 1, wherein in the first operation, the tungsten-containing gas is supplied first, and , the reducing gas is supplied after the supplying of the tungsten-containing gas is completed.

3. The method of claim 2, wherein in the first operation, a supply end time regarding the tungsten-containing gas is substantially identical to a supply start time regarding the reducing gas.

4. The method of claim 2, wherein in the first operation, an interval exists between the supply end time regarding the tungsten-containing gas and the supply start time regarding the reducing gas.

5. The method of claim 1, wherein in the first operation, the reducing gas is supplied first, and the tungsten-containing gas is supplied after the supplying of the reducing gas is completed.

6. The method of claim 1, wherein in the first operation, the process pressure inside the process chamber is from about 10 Torr to about 40 Torr, and the process temperature inside the process chamber is from about 300° C. to about 400° C.

7. The method of claim 1, wherein in the second operation, a purge gas is supplied into the process chamber, the process chamber is vacuum-exhausted, or the process chamber is vacuum-exhausted while supplying the purge gas into the process chamber.

8. The method of claim 7, wherein the purge gas includes an inert gas.

9. The method of claim 1, wherein the performing a tungsten nucleation layer forming operation forms the tungsten nucleation layer having a desired thickness by forming a portion of the tungsten nucleation layer and purging the process chamber two or more times.

10. The method of claim 1, wherein a thickness of the tungsten bulk layer is greater than a thickness of the tungsten nucleation layer.

11. A method of fabricating a semiconductor device, the method comprising:
forming a plurality of concave-convex patterns on a substrate;
forming an insulation film on the plurality of concave-convex patterns;
disposing the substrate including the plurality of concave-convex and the insulation film inside a process chamber;
performing a tungsten nucleation layer forming operation for forming a tungsten nucleation layer on the insulation film;
performing a first operation for forming a portion of a tungsten bulk layer on the tungsten nucleation layer by alternately supplying a tungsten-containing gas and a reducing gas into the process chamber; and
performing a second operation for stopping the supply of the tungsten-containing gas and the reducing gas and removing a remaining gas in the process chamber,
wherein a tungsten film that fully covers the plurality of concave-convex patterns is formed by repeatedly performing the first operation and the second operation two or more, until the tungsten bulk layer reaches a target thickness.

12. The method of claim 11, wherein in the first operation, the tungsten-containing gas is supplied first, and the reducing gas is supplied after the supplying of the tungsten-containing gas is completed, or
the reducing gas is supplied first and, the tungsten-containing gas is supplied after the supplying of the reducing gas is completed,.

13. The method of claim 11, wherein in the first operation, at least one of the process pressure or the process temperature inside the process chamber is set to be higher than that in the tungsten nucleation layer forming operation.

14. The method of claim 11, wherein the tungsten bulk layer is formed on the plurality of concave-convex patterns in a Frank-van der Merwe (FM) mode.

15. The method of claim 11, wherein the tungsten film forms a plurality of word lines that form memory cells of the semiconductor device.

16. A method of forming a tungsten film, the method comprising:
disposing a substrate in a process chamber;
performing a SiH₄ based reduction reaction with regard to a tungsten containing gas to form a tungsten nucleation layer on the substrate;
performing a H₂ based reduction reaction with regard to the tungsten-containing gas to form a tungsten bulk layer on the tungsten nucleation layer; and
stopping supply of the tungsten-containing gas and H₂ gas, and removing a remaining gas in the process chamber,
wherein the performing a H₂ based reduction reaction and the stopping and removing are repeated until the tungsten bulk layer reaches a target thickness.

17. The method of claim 16, wherein the performing a H₂ based reduction reaction includes alternately supplying the tungsten-containing gas and the H₂ gas into the process chamber in a pulsed manner.

18. The method of claim 16, wherein the performing a H₂ based reduction reaction includes:
supplying the tungsten-containing gas first, and supplying the H₂ gas after the supplying of the tungsten-containing gas is completed; or
supplying the H₂ gas first, and supplying the tungsten-containing gas after the supplying of the H₂ gas is completed.

19. The method of claim 16, wherein in the performing a H₂ based reduction reaction, a supply end time regarding the tungsten-containing gas is substantially identical to a supply start time regarding the H₂ gas.

20. The method of claim 16, wherein in the performing a H₂ based reduction reaction, an interval exists between a supply end time regarding the tungsten-containing gas and a supply start time regarding the H₂ gas.
